(19) United States
(12) Patent Application Publication
(10) Pub. No.: US 2017/0092463 A1
(43) Pub. Date: Mar. 30, 2017

(54) WAFER MANUFACTURING SYSTEM AND RELATED PROCESS

(71) Applicant: Rayton Solar Inc., Santa Monica, CA (US)

(72) Inventors: Andrew X. Yakub, Stevenson Ranch, CA (US); James Benjamin Rosenzweig, Los Angeles, CA (US); Mark Stanley Goorsky, Valencia, CA (US)

(21) Appl. No.: 15/376,455

(22) Filed: Dec. 12, 2016

Related U.S. Application Data
(63) Continuation-in-part of application No. 15/354,957, filed on Nov. 17, 2016.
Application No. 15/354,957 is a continuation of application No. 14/625,544, filed on Feb. 18, 2015, now Pat. No. 9,499,921.
Application No. 14/625,544 is a continuation-in-part of application No. 13/954,868, filed on Jul. 30, 2013, now Pat. No. 9,404,198.
(60) Provisional application No. 61/941,325, filed on Feb. 18, 2014.
(60) Provisional application No. 61/677,392, filed on Jul. 30, 2012.

(51) Int. Cl. H01J 37/31; H01J 37/20; H01J 37/305

(52) U.S. Cl. CPC H01J 37/31; H01J 37/305; H01J 37/20; H01J 2237/002

(57) ABSTRACT

The process for manufacturing a semiconductor wafer includes steps for mounting a semiconductor work piece for exfoliation, energizing a microwave device for generating an energized beam sufficient for penetrating an outer surface layer of the semiconductor work piece, exfoliating the outer surface layer of the semiconductor work piece with the energized beam, and removing the exfoliated outer surface layer from the semiconductor work piece as the semiconductor wafer having a thickness less than 100 micrometers.

### BACKGROUND OF THE INVENTION

The present invention generally relates to processes and apparatuses for manufacturing wafers. More particularly, the invention relates to processes and apparatuses for exfoliating the external surface of an ingot to more efficiently produce solar grade photovoltaic wafers and the like therefrom.

Conventionally, a wafer material such as monocrystalline silicon is processed into solar grade photovoltaic (“PV”) wafers by first creating a single crystalline cylindrical ingot of silicon. The ingot is created by melting high-purity semiconductor-grade wafer material in an inert chamber, such as one made of quartz. Dopant impurity atoms such as boron, phosphorus, arsenic, or antimony may be added to the molten wafer material in precise amounts (e.g., on the order of 10¹³ or 10¹⁶ atoms per cm³) to define the material as either a bulk n-type (negative) or p-type (positive) semiconductor, which gives the wafer material the desired electrical properties. Then, a rod-mounted seed crystal is dipped into the molten wafer material and slowly pulled upwards and rotated simultaneously to extract a preferably single-crystal cylindrical ingot. Controlling the temperature gradient, extraction rate, and rotation speed facilitates the production of a single ingot with only trace amounts of unwanted instabilities. The process is normally performed in an inert atmosphere such as argon.

Individual wafers are basically created by slicing a thin layer of the semiconductor material off from this larger ingot. Wafers may be square, rectangular or circular and are frequently used in the fabrication of integrated circuits and other micro or electronic devices, such as solar panels. In one example, circular wafers are sliced off the end of the cylindrical ingot by a diamond coated wire roughly 20 micrometers in diameter. The problem with this production method is that the diamond wire shaves a portion of the ingot into dust in a thickness equal to the diameter of the diamond coated wire. Thus, for each circular wafer created, at least 20 micrometers of wafer material is wasted as dust residue.

But, these circular wafers are not preferred for use with solar panels because square or rectangular wafers better maximize surface area exposure to sunlight energy. To make square or rectangular wafers, the stock cylindrical ingot is, instead, first squared into an elongated rectangular box shape approximately 1.5 meters long. This squaring process uses a similar conventional 20 micrometer diameter diamond coated wire. Similar to the above, portions of the exterior of the ingot are lost to dust as the diamond wire cuts through portions of the ingot to form the rectangular block. Furthermore, this squaring process requires relatively large chunks of valuable and expensive wafer material to be chopped off and thrown away to square the cylindrical ingot. From here, individual square or somewhat rectangular wafers are sliced off the end of the rectangular semiconductor block, as described above with respect to the circular wafers. While hundreds of relatively square or rectangular wafers ranging in thickness from 160 to 200 micrometers can be sliced off this rectangular semiconductor block, each wafer cut wastes an amount of wafer material equal to the width of the diamond wire cutting the semiconductor block. Another drawback in cutting wafers with a diamond-coated wire is that the saw can cause surface damage to the wafer that requires repair.

Recently, newer technologies have been developed to create additional, thinner wafers from existing wafers cut from the silicon ingot or rectangular silicon block, as described above. For example, U.S. Pat. No. 7,939,812 to Glavish et al., U.S. Pat. No. 7,982,197 to Smick et al., U.S. Pat. No. 7,989,784 to Glavish et al., and U.S. Pat. No. 8,044,374 to Ryding et al., the contents of each reference are herein incorporated by reference in their entireties, disclose a hydrogen ion implanter used to exfoliate silicon wafers to produce a thinner lamina of crystalline semiconductor material. In this respect, the ion implanter penetrates the surface of a silicon wafer to a certain depth. This penetrated layer of silicon can then be peeled back away from the silicon wafer (i.e., exfoliated)—effectively creating a thinner silicon wafer using the original silicon wafer as a workpiece. Using this exfoliation process, a silicon wafer workpiece on the order of 160-200 micrometers can be used to create 8-10 new silicon wafers having a thickness of approximately 20 micrometers, with nearly no silicon material wasted during the process. Further to this concept, U.S. Pat. Nos. 8,058,626 and 8,089,050, both to Purser et al., the contents of which are both herein incorporated by reference, disclose embodiments for creating a modified ribbon-shaped ion beam having an elongated cross-section normal to the beam direction for use in the aforementioned process for implanting ions into the surface of a substrate.

The current exfoliation processes, such as those described above, require two steps to create a sheet of exfoliated wafer material. More specifically, individual wafers are exfoliated from an ingot in one process step and then the exfoliated layer or wafer is removed from the ingot in a second process step. This two-step conventional process is costly and time consuming by virtue of its multi-step nature. Furthermore, this conventional process produces a large number of individual exfoliated sheets of wafer material that are relatively expensive to handle and stamp into individual wafers.

Typically, conventional solar cells are manufactured from silicon produced through the Czochralski process, which can result in undesirably high oxygen content (e.g., 10¹⁸ oxygen atoms per cubic centimeter) as a result of using a crucible. Impurities in silicon wafers, such as oxygen, reduce the voltage and current capacities of the solar cell. As such, lower oxygen content silicon such as float zone silicon (“FZ silicon”) are more desirable as FZ silicon produces more efficient solar cells. FZ silicon is made in a process called vertical zone melting, wherein a polycrystalline rod of ultra-pure electronic grade silicon is passed through an RF heating coil to create a localized molten zone. A seed crystal is used at one end of the rod to start crystal ingot growth. The vertical zone melting process is carried out in an evacuated chamber or in an inert gas purge. Unlike the Czochralski process, the molten zone carries impurities such as oxygen away from the silicon ingot during growth (e.g., because most impurities are more soluble in the melt than the crystal), thereby reducing the impurity concentration within the silicon ingot. As such, FZ silicon is relatively more pure than silicon made from the Czochralski process. But, the problem with FZ silicon is that it must be cut into thicker than desired wafer sizes (e.g., on the order of 300-500 microns in thickness) because the rigid material properties prevent known methods (e.g., a diamond wire) from cutting the material any thinner. Thus, silicon wafers made from FZ silicon or the like are currently cost prohibitive due to material costs and limitations regarding the currently available minimum manufacturing thickness of the wafers.

There exists, therefore, a significant need in the art for processes and related apparatuses for more efficiently producing square and rectangular wafers. Such processes and related apparatuses may include steps for mounting a square or rectangular workpiece, penetrating a selected layer of the outer surface of the workpiece, exfoliating away this bombarded layer of workpiece material along one or more sides of the rectangular or square workpiece, and conveying that strip of material to a press to be sliced into individual wafers, all without the waste associated with cutting or slicing the workpiece into individual wafers with a diamond saw. Such processes and apparatuses may further be able to simultaneously exfoliate and remove a single continuous sheet of wafer material from the workpiece. The present invention fulfills these needs and provides further related advantages.

### SUMMARY OF THE INVENTION

In one embodiment for a method of manufacturing a semiconductor wafer, the method includes the steps of mounting a semiconductor work piece for exfoliation, energizing a microwave device for generating an energized beam sufficient for penetrating an outer surface layer of the semiconductor work piece, exfoliating the outer surface layer of the semiconductor work piece with the energized beam, applying a coolant directly to the outer surface layer of the semiconductor work piece for cooling the semiconductor work piece at a penetration point where the energized beam bombards the outer surface layer of the semiconductor work piece, and removing the exfoliated outer surface layer from the semiconductor work piece as the semiconductor wafer.

More specifically, the semiconductor work piece may include a pre-cut semiconductor work piece that has a thickness of 100 microns to 1 meter and may be a type III-V semiconductor material or a type IV semiconductor material. In this respect, the type III-V semiconductor material may include gallium arsenide and the type IV semiconductor material may include silicon or germanium. The final semiconductor wafer made from a semiconductor work piece or a pre-cut semiconductor work piece may have a thickness less than 100 microns, and more specifically 2-70 microns. The oxygen content of such a semiconductor work piece and resulting semiconductor wafer may be less than 10¹⁵ oxygen atoms per cubic centimeter. In one embodiment, the semiconductor work piece may have a rectangular shape and the semiconductor wafer may be a square semiconductor wafer.

In another aspect of this embodiment, the microwave device may include a high current particle accelerator that creates an energized beam having an implantation density of approximately 1×10¹⁷ ions/cm². More specifically, the high current particle accelerator may include an electron cyclotron resonance ion source or a radio-frequency quadrupole (RFQ) accelerator and the energized beam may have a width approximately the same as the width of the semiconductor work piece.

In another embodiment as disclosed herein, a method for manufacturing a semiconductor wafer includes steps of mounting a semiconductor work piece having an oxygen content less than 10¹⁵ oxygen atoms per cubic centimeter, energizing a microwave device for generating an energized beam having an implantation density of approximately 1×10¹⁷ ions/cm² for penetrating an outer surface layer of the semiconductor work piece, exfoliating the outer surface layer of the semiconductor work piece with the energized beam, applying a coolant directly to the outer surface layer of the semiconductor work piece for cooling the semiconductor work piece at a penetration point where the energized beam bombards the outer surface layer of the semiconductor work piece, and removing the exfoliated outer surface layer from the semiconductor work piece as the semiconductor wafer having a thickness less than 100 micrometers.

More specifically, the semiconductor work piece may include a type III-V semiconductor material selected from the group consisting of gallium arsenide, indium phosphide, boron nitride, boron phosphide, boron arsenide, aluminum nitride, aluminum phosphide, aluminum arsenide, aluminum antimonide, gallium nitride, gallium phosphide, gallium antimonide, indium nitride, indium arsenide, or indium antimonide. Alternatively, the semiconductor work piece may include a type IV semiconductor selected from the group consisting of monocyrstalline silicon, polycrystalline silicon, or germanium. The semiconductor work piece may include a pre-cut semiconductor work piece having a thickness of 100 microns to 1 meter. The semiconductor wafer may include a square semiconductor wafer having a thickness of 2-70 microns, or more specifically a thickness of 4-20 microns. Exfoliating the semiconductor wafer may form multiple semiconductor wafers, wherein each of the semiconductor wafers are moved by way of a conveyor or a handle.

The microwave device may include an electronic cyclotron resonance ion source or a radio-frequency (RFQ) accelerator for generating the energized beam that includes an ion beam or a proton beam. The energized beam may move relative to the semiconductor work piece or the energized beam may include a width approximately the same as the width of a rectangular semiconductor work piece so the energized beam is not required to move relative to the semiconductor work piece.

In another embodiment, a method for manufacturing a plurality of semiconductor wafers may include steps for mounting a pre-cut semiconductor work piece that has an oxygen content less than 10¹⁵ oxygen atoms per cubic centimeter and having a thickness of 160-600 microns. Here, the semiconductor work piece may include a type III-V semiconductor selected from the group consisting of gallium arsenide, indium phosphide, boron nitride, boron phosphide, boron arsenide, aluminum nitride, aluminum phosphide, aluminum arsenide, aluminum antimonide, gallium nitride, gallium phosphide, gallium antimonide, indium nitride, indium arsenide, or indium antimonide. Additionally, a microwave device that includes an electron cyclotron resonance ion source or a radio-frequency quadrupole (RFQ) may generate an energized beam sufficient for penetrating an outer surface layer of the semiconductor work piece. This, accordingly, may exfoliate an outer surface layer of the semiconductor work piece. Applying a coolant directly to the outer surface layer of the semiconductor work piece may cool the semiconductor work piece at a penetration point where the energized beam bombards the outer surface layer of the semiconductor work piece. Accordingly, the exfoliated outer surface layer may be removed from the semiconductor work piece as the semiconductor wafer having a thickness of 2-70 microns. The semiconductor wafer may be further cut into multiple semiconductor wafers.

One embodiment for an apparatus for manufacturing a plurality of semiconductor wafers from a semiconductor work piece may include a mount for selectively receiving and retaining the semiconductor work piece having an exfoliation surface. A microwave may be positioned relative to the mount to emit an energized beam in the direction of the exfoliation surface. The relative movement of the microwave and the semiconductor work piece may exfoliate a semiconductor wafer therefrom. A fluid cooler (e.g., an air or water cooler) may be positioned to apply a coolant directly to an outer surface layer of the semiconductor work piece to cool a penetration point where the energized beam bombards the outer surface layer of the semiconductor work piece for controlling a surface temperature of the semiconductor work piece during exfoliation. To this end, a handle may be used to remove each of the plurality of semiconductor wafers exfoliated from the exfoliation surface away from the semiconductor work piece.

In other aspects of this embodiment, the semiconductor work piece may include a type IV semiconductor selected from the group consisting of monocyrstalline silicon, polycrystalline silicon, or germanium, or the semiconductor work piece may be a type III-V semiconductor selected from the group consisting of gallium arsenide, indium phosphide, boron nitride, boron phosphide, boron arsenide, aluminum nitride, aluminum phosphide, aluminum arsenide, aluminum antimonide, gallium nitride, gallium phosphide, gallium antimonide, indium nitride, indium arsenide, or indium antimonide. Additionally, the microwave device may include an electron cyclotron resonance ion source or a radio-frequency quadrupole (RFQ) that generates an elongated beam approximately the width of the exfoliation surface. To this end, the semiconductor work piece may include a rectangular shape and an oxygen content less than 10¹⁵ oxygen atoms per cubic centimeter, wherein the semiconductor wafer includes a thickness less than 100 microns.

Another method for manufacturing a silicon wafer as disclosed herein, includes mounting a float zone silicon work piece for exfoliation, energizing a microwave device for generating an energized beam sufficient for penetrating an outer surface layer of the float zone silicon work piece, exfoliating the outer surface layer of the float zone silicon work piece with the energized beam and removing the exfoliated outer surface layer from the float zone silicon work piece as the silicon wafer having a thickness less than 100 micrometers, or more specifically a thickness of 2-70 microns or 4-20 microns. In one embodiment, the float zone silicon work piece may be a pre-cut float zone silicon work piece having a thickness of 160-600 microns and an oxygen content less than 10¹⁶ oxygen atoms per cubic centimeter.

The method may also include steps for cutting the silicon wafer into multiple silicon wafers and moving or conveying each of those multiple silicon wafers along a conveyor and away from the float zone silicon work piece. In one embodiment, the silicon wafers may be square. In another embodiment, the silicon wafers may be rectangular and be exfoliated from a rectangular float zone silicon work piece. Furthermore, the microwave device may include a klystron for generating an energized beam that includes an ion beam or a proton beam and may approximately span the width of the float zone silicon work piece. In one embodiment, the energized beam may move relative to the float zone silicon work piece and include an implantation density of between 5×10¹⁴ and 5×10¹⁶ ions/cm².

In an alternative embodiment, another method for manufacturing a silicon wafer includes mounting a float zone silicon work piece having an oxygen content less than 10¹⁶ oxygen atoms per cubic centimeter, energizing a microwave device for generating an energized beam having an implantation density of approximately 5×10¹⁴ to 5×10¹⁶ ions/cm² for penetrating an outer surface layer of the float zone silicon work piece, exfoliating the outer surface layer of the float zone silicon work piece with the energized beam, and removing the exfoliated outer surface layer from the float zone silicon work piece as the silicon wafer. The silicon wafer may have a thickness less than 100 micrometers, and more specifically a thickness of 4-20 microns. Additionally, the silicon wafers may be cut into multiple silicon wafers and moved away from the work piece along a conveyor.

Additionally, the float zone silicon work piece may include a pre-cut float zone silicon work piece having a thickness of 160-600 microns, which may form square silicon wafers having a thickness of 2-70 microns. In this embodiment, the microwave device may include a klystron for generating the energized beam, which may include an ion beam or a proton beam. The energized beam may also move relative to the float zone silicon work piece or be approximately the same width as a rectangular float zone silicon work piece.

In another alternative method, manufacturing a plurality of silicon wafers may include steps for mounting a pre-cut float zone silicon work piece having an oxygen content less than 10¹⁶ oxygen atoms per cubic centimeter and having a thickness of 160-600 microns, energizing a microwave device for generating an energized beam sufficient for penetrating an outer surface layer of the float zone silicon work piece, exfoliating the outer surface layer of the float zone silicon work piece with the energized beam, wherein the energized beam moves relative to the float zone silicon work piece, removing the exfoliated outer surface layer from the float zone silicon work piece as the silicon wafer that includes a thickness of 2-70 microns, cutting the silicon wafer into multiple silicon wafers, and moving each of the multiple silicon wafers along a conveyor.

An apparatus as disclosed herein for manufacturing a plurality of silicon wafers from a float zone silicon work piece may include a mount for selectively receiving and retaining the float zone silicon work piece having an exfoliation surface. A microwave may produce an energized beam that has an implantation density of approximately 5×10¹⁴ to 5×10¹⁶ ions/cm². The microwave may be positioned relative to the mount to emit the energized beam in the direction of the exfoliation surface, wherein relative movement of the microwave and the float zone silicon work piece exfoliates a silicon wafer having a thickness of less than 100 microns. A conveyor then longitudinally carries each of the plurality of silicon wafers exfoliated from the exfoliation surface away from the float zone silicon work piece.

In one embodiment, the microwave may include a klystron or a DC accelerator, the energized beam may include an ion beam or a proton beam, and may be an elongated beam approximately the width of the exfoliation surface. Additionally, the float zone silicon work piece may include a rectangular shape and have an oxygen content less than 10¹⁶ oxygen atoms per cubic centimeter. The silicon wafer exfoliated from the float zone silicon work piece may have a thickness of 2-70 microns.

In additional alternative embodiments, the process for manufacturing wafers as disclosed herein includes the steps of mounting an ingot as a work piece in a manner that permits rotation about a longitudinal axis of rotation and rotating the ingot about the longitudinal axis of rotation. Here, the ingot may be in the shape of a cylinder and may be carried by a rotatable shaft mountable to a rotor that facilitates the rotation of the cylindrical ingot about its longitudinal axis of rotation. The ingot may be made from monocrystalline or polycrystalline silicon. A microwave device for generating an energized beam sufficient for penetrating an outer surface layer of the rotating ingot is then energized. Accordingly, the outer surface layer of the rotating ingot is exfoliated with the energized beam. As the ingot continues to rotate, the exfoliated outer surface layer can then be removed from the ingot work piece as a continuous planar strip that can be cut into a wafer. At this time, the continuous planar strip may be transported along a conveyor moving at approximately the same speed as or substantially synchronized with the angular velocity of the rotating ingot. In the event the ingot is incrementally rotated, the conveyor would also incrementally move the continuous planar strip forward in a similar incremental movement. Of course, the continuous strip may be cut or stamped by a press into a plurality of wafers.

Additionally, the wafer manufacturing process may also include the step of cooling the ingot at a penetration point where the energized beam bombards the outer surface layer of the ingot to prevent the chemical properties of the ingot material from changing as a result of increased local temperatures. Such a cooling step can be used when the energized beam operates at an energy level between 0.15-1.7 megaelectron volts. The microwave device may be a klystron that generates an energized beam that includes a proton beam or an ion beam. Additionally, the microwave device may be calibrated to maximize a Q value and the energized beam may include multiple energized beams that simultaneously exfoliate respective outer surface layers of the rotating ingot, to simultaneously create multiple respective exfoliated outer surface layers that can be peeled or removed from the ingot work piece. In one embodiment, the energized beam(s) are approximately the width of the final wafer product. For example, the wafer may be square and have a width of between 160-200 mm with an outer surface layer thickness between 3-30 micrometers.

In another process for manufacturing wafers as disclosed herein, an ingot formed in the shape of a cylinder and carried by a rotatable shaft is mounted to a rotor capable of rotating the cylindrical ingot about its longitudinal axis of rotation. Next, the rotor activates and rotates the cylindrical ingot such that an energized beam generated by a microwave device can penetrate a predetermined outer surface layer of the rotating ingot. This permits the manufacturing process to exfoliate the outer surface layer away from the cylindrical ingot work piece as a continuous planar strip along a conveyor synchronized with the rotating ingot. The cylindrical ingot work piece may be cooled at the penetration point where the energized beam bombards the outer surface layer, to prevent the chemical properties of the ingot material from changing as a result of increased localized temperatures. The continuous strip of material is then stamped into a plurality of wafers usable in, for example, a solar panel or the like.

The microwave device may be calibrated to maximize a Q value so that an energized beam having an energy level between 0.15-1.7 megaelectron volts efficiently penetrates the outer surface of the rotating cylindrical ingot. In one embodiment, the microwave device is a klystron that generates a proton or ion energized beam. In another embodiment, the microwave device utilizes Electron Cyclotron Resonance to produce high current ions. Moreover, the process may include the use of multiple energized beams that simultaneously exfoliate respective outer surface sections of the rotating ingot, to more efficiently exfoliate the outer surface of the ingot along its entire vertical height. The energized beam may be approximately the width of the wafer product, such as between 160-200 mm. The cylindrical ingot may be made from monocrystalline or polycrystalline silicon and be rotated incrementally so that approximately an outer surface layer thickness between 3-30 micrometers is exfoliated.

The apparatus for manufacturing a wafer may include a rotator configured to selectively mountably receive and rotate an ingot work piece about a longitudinal axis of rotation. The ingot may be cylindrical and may be made from monocrystalline or polycrystalline silicon. A microwave for producing an energized beam may be positioned relative to the rotator such that the emitted energized beam aligns with the longitudinal axis of rotation of the rotating ingot. The energized beam may be of an energy level sufficient to penetrate an outer surface layer of the rotating ingot. A water cooler or an air cooler positioned proximate to a penetration point where the energized beam bombards the outer surface layer of the ingot may control the surface temperature therein during manufacturing. The apparatus may also include a conveyor synchronized with the rotating ingot to transversely carry as a continuous planar strip an exfoliated outer surface layer away from the rotating ingot. This continuous planar strip is then cut into one or more wafers by a cutting mechanism. In this respect, such a cutting mechanism may include a stamping die that cuts the continuous strip into multiple wafers with each stroke. The final wafer product may be of a width between 160-200 mm and a thickness between 3-30 micrometers. In one embodiment, the microwave may be a klystron that includes an energy accelerator. To this end, the energized beam may be an ion beam or a proton beam, and may be an elongated beam approximately the width of said wafer.

Other features and advantages of the present invention will become apparent from the following more detailed description, when taken in conjunction with the accompanying drawings, which illustrate, by way of example, the principles of the invention.

### BRIEF DESCRIPTION OF THE DRAWINGS

The accompanying drawings illustrate the invention. In such drawings:

FIG. 1 is a flowchart illustrating the steps used in association with a method and process for manufacturing a wafer;

FIG. 2A is a diagrammatic view illustrating melting high-purity semiconductor grade wafer material with dopants in an inert chamber;

FIG. 2B is a diagrammatic view illustrating lowering a seed crystal mounted to one end of a rotatable shaft into the melted mixture;

FIG. 2C is a diagrammatic view illustrating catalytic crystallization of the melted mixture to the seed crystal;

FIG. 2D is a diagrammatic view illustrating formation of an ingot through controlled removal of the seed crystal from the mixture;

FIG. 2E is a diagrammatic view illustrating complete formation of an ingot from the melted mixture;

FIG. 3 is a diagrammatic perspective view illustrating mounting of the ingot at one end to a rotator;

FIG. 4 is a diagrammatic perspective view illustrating rotation of the ingot about its longitudinal axis when alternatively coupled to two rotators;

FIG. 5A is a partial cut-away diagrammatic perspective view illustrating bombardment of the outer surface of the ingot with one or more beams;

FIG. 5B is an alternative cut-away diagrammatic perspective view illustrating bombardment of the outer surface of the ingot with one or more elongated beams;

FIG. 6 is a diagrammatic side view of the ingot, illustrating protons penetrating the outer surface of the ingot to a predetermined depth;

FIG. 7 is a diagrammatic side view of the ingot, illustrating exfoliation of the ingot;

FIG. 8A is a diagrammatic top view of the bombarded ingot, illustrating single layer exfoliation;

FIG. 8B is an alternative diagrammatic top view of the bombarded ingot, illustrating multi-layer exfoliation;

FIG. 9 is a diagrammatic side view illustrating conveying the exfoliated layer away from the ingot;

FIG. 10 is a diagrammatic side view illustrating cutting the exfoliated layer into individual wafers;

FIG. 11 is a diagrammatic view illustrating cutting a cylindrical ingot into a square or rectangular ingot with a diamond wire;

FIG. 12A is a diagrammatic perspective view illustrating bombardment of the outer front work surface of the squared off ingot of FIG. 11 with an elongated beam;

FIG. 12B is a diagrammatic perspective view illustrating bombardment of the outer side work surface of the squared off ingot of FIG. 11 with an elongated beam;

FIG. 13A is a diagrammatic perspective view illustrating an exfoliated layer peeling away from the front work surface exfoliated in FIG. 12A;

FIG. 13B is a diagrammatic perspective view illustrating an exfoliated layer peeling away from the side work surface exfoliated in FIG. 12B; and

FIG. 14 is a diagrammatic side view illustrating the exfoliated layers being carried away from the work piece by a conveyor.

### DETAILED DESCRIPTION OF THE PREFERRED EMBODIMENTS

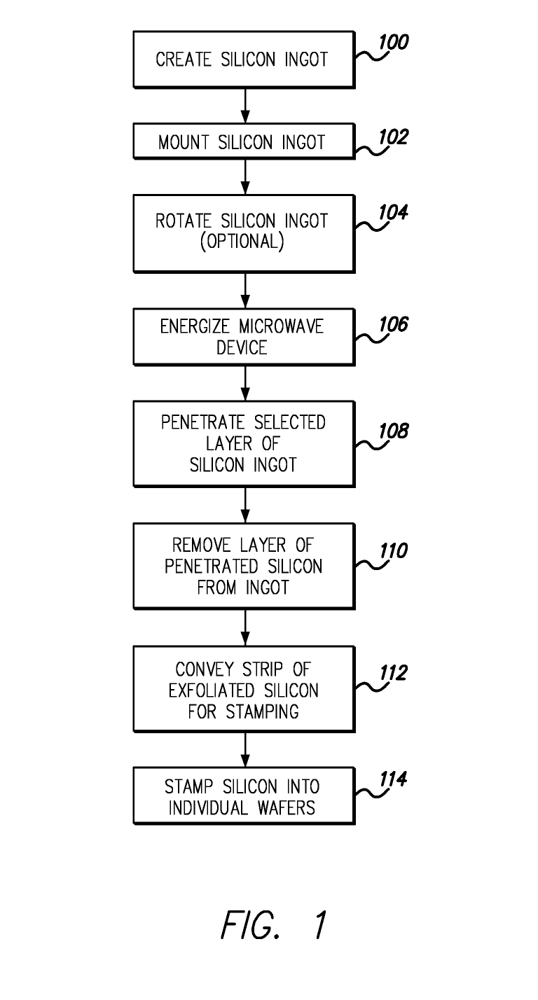

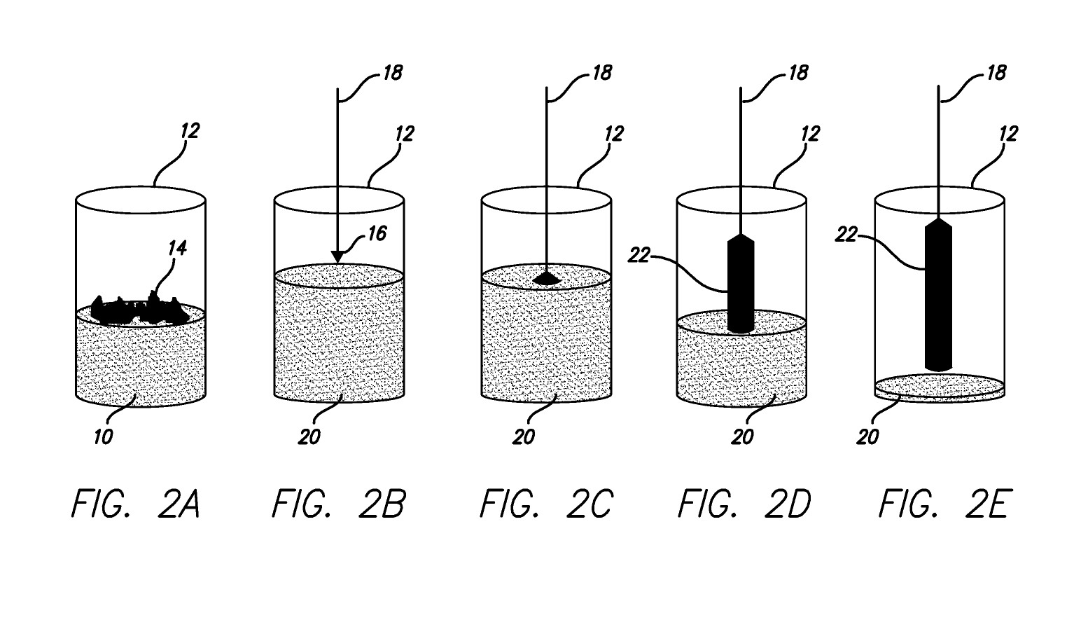

As shown in the drawings for purposes of illustration, the present invention for the improved processes for manufacturing wafers is shown generally with respect to the flowchart in FIG. 1 and the operation of the manufacturing process is shown in more detail in FIGS. 2-10. More specifically, the first step, as shown in FIG. 1, is to create an ingot 100. In one embodiment, the ingot 100 may be a type IV semiconductor such as a monocyrstalline or polycrystalline cylindrical silicon ingot or a germanium ingot. In another embodiment, the ingot 100 may be any other semiconductor material suitable for exfoliation, such as any type III-V semiconductor material such as gallium arsenide, indium phosphide, boron nitride, boron phosphide, boron arsenide, aluminum nitride, aluminum phosphide, aluminum arsenide, aluminum antimonide, gallium nitride, gallium phosphide, gallium antimonide, indium nitride, indium arsenide, indium antimonide, etc. Moreover, the ingot 100 may have any cross-sectional shape, such as a polygonal cross-sectional shape. One set of processes and apparatuses disclosed herein aim to, inter alia, reduce the waste associated with squaring off a cylindrical ingot used as a workpiece for creating square or rectangular semiconductor wafers for use with solar panels and the like. Furthermore, the processes and apparatuses disclosed herein are able to further reduce wasted wafer material by at least one order of magnitude for each wafer created in view of eliminating the need to slice individual wafers using the aforementioned diamond coated wire. Accordingly, eliminating both of these wasteful steps in producing solar grade semiconductor photovoltaic material corresponds to a cost savings of the same magnitude. Thus, as will be described in more detail below, the amount of solar PV material produced increases by a factor of at least 20 over the same ingot used by traditional or conventional manufacturing methods. This obviously corresponds to tremendous cost savings in raw material. Additionally, simultaneously exfoliating and removing a continuous sheet of wafer material from the ingot, as described in more detail below, eliminates the need for the relatively more cost intensive two-step exfoliation process and decreases the costs associated with handling numerous individual sheets of exfoliated wafer material, as is known in the prior art.

As shown in FIG. 2A, high-purity semiconductor-grade wafer material 10 is melted in an inert chamber 12, such as a chamber made from quartz. Of course, as mentioned above, the wafer material 10 may be any semiconductor material suitable for exfoliation, such as a type IV semiconductor material such as monocyrstalline silicon, polycrystalline silicon, or geranium, or any type III-V semiconductor material such as gallium arsenide, indium phosphide, boron nitride, boron phosphide, boron arsenide, aluminum nitride, aluminum phosphide, aluminum arsenide, aluminum antimonide, gallium nitride, gallium phosphide, gallium antimonide, indium nitride, indium arsenide, indium antimonide, etc. Dopants 14 (e.g., boron, phosphorus, arsenic, or antimony) may be added to the melted wafer material 10 to add impurities thereto, preferably on the order of 10¹³ or 10¹⁶ atoms per cm³ to polarize the composition as a n-type (negative) or p-type (positive) semiconductor. A seed crystal 16 mounted to one end of a rotatable shaft 18 is then lowered into this somewhat impure mixture 20 of the melted wafer material 10 and the dopants 14 to begin the crystallization process as shown in FIG. 2B. The seed crystal 16, once immersed into this mixture 20 as shown in FIG. 2C, acts as a catalyst to start crystallization of the melted wafer material mixture 20 about the shaft 18. The shaft 18 is then slowly pulled upwards and rotated simultaneously to extract a large ingot 22 from the melt. The ingot 22 may be a single-crystal cylindrical ingot, a polycrystalline cylindrical ingot, or another semiconductor cylindrical ingot, such as any type IV semiconductor material (e.g., geranium) or any type III-V semiconductor material such as gallium arsenide, indium phosphide, boron nitride, boron phosphide, boron arsenide, aluminum nitride, aluminum phosphide, aluminum arsenide, aluminum antimonide, gallium nitride, gallium phosphide, gallium antimonide, indium nitride, indium arsenide, indium antimonide, etc. Of course, the ingot 22 may be made from another semiconductor material known in the art. The crystallization of the ingot 22 formed from the mixture 20 is indicated by the decreased amount of the mixture 20 in the inert chamber 12, progressing from FIG. 2C to FIG. 2E. In this respect, FIG. 2E illustrates one ingot 22 for use with the processes disclosed herein.

Persons of ordinary skill in the art will readily recognize that the above-described process for creating the ingot 22 in accordance with step 100 may vary depending on the desired application and end characteristics of the wafer. For example, one may vary the composition of the melted wafer material 10, the amount and/or types of dopants 14 introduced into and mixed with the melted wafer material 10, the temperature in the inert chamber 12, the angular rotating speed of the shaft 18, and the rate of extracting the seed crystal 16. In this respect, the wafer material creation process 100 should be considered well known to those skilled in the art. In one embodiment, the ingot 22 may be an FZ silicon ingot made by the vertical zone melting process to reduce the number of impurities therein, especially oxygen impurities.

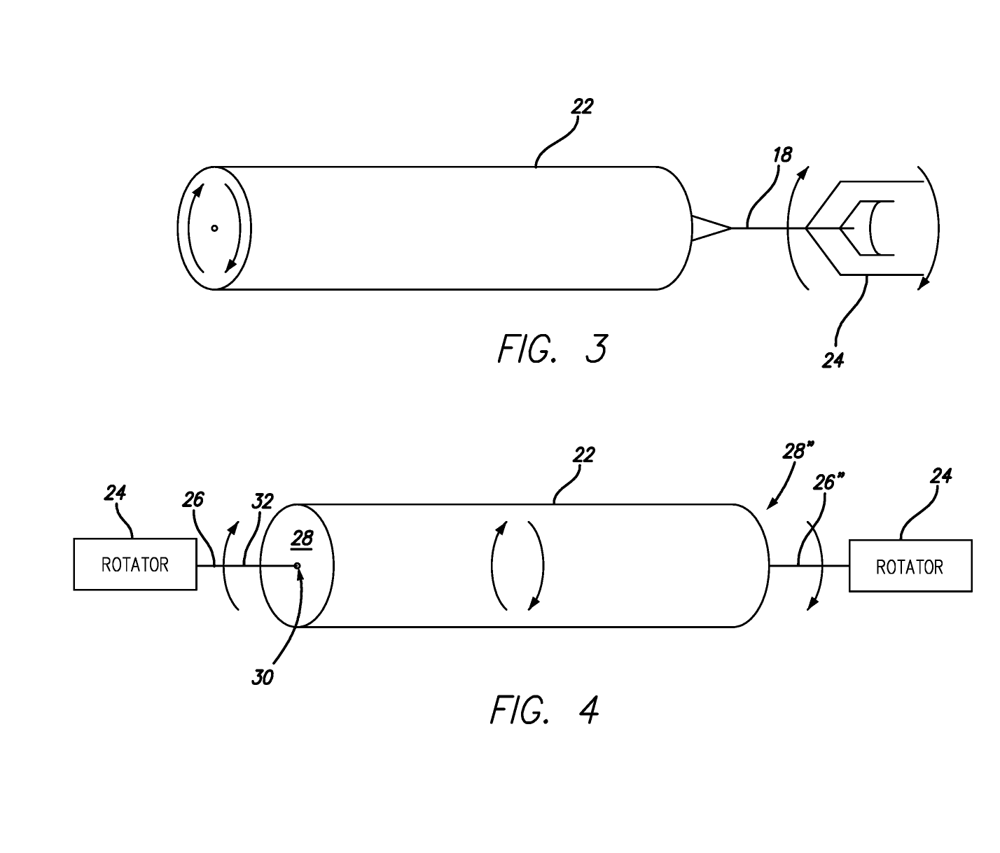

Once the ingot 22 has been created during step 100, the next step 102 in accordance with FIG. 1 is to mount the ingot 22 in preparation for the exfoliation process. In one embodiment, the ingot 22 remains stationary after being mounted. In another embodiment, the ingot 22 may be mounted to the rotator 24, as illustrated in FIG. 3, which may couple to the shaft 18 or other extension extending out from the body of the ingot 22. In this embodiment, the rotator 24 may be capable of holding and rotating the ingot 22 in the generally horizontal position shown with respect to FIG. 3. Alternatively, as shown in FIG. 4, a pair of rotation arms 26, 26′ may extend out from or comprise a portion of the rotator (generally designated as numeral 24) and attach to a pair of planar end surfaces 28, 28′ of the ingot 22. Here, the rotation arms 26, 26′ may include an attachment mechanism 30 in the form of a grip, clamp, or other device having a high friction surface to retain (e.g., by compression fit) the ingot 22 therebetween. In this respect, any attachment mechanism 30 known in the art capable of supporting and rotating the ingot 22 at a stable and consistent speed in connection with the rotator 24 will suffice. Moreover, the rotator(s) 24, the rotation arms 26, 26′ or the attachment mechanism 30 could also be utilized individually or in combination with one another to move the mounted ingot 22 back and forth about its axis of rotation 32 during the ion implantation process, as described in more detail below.

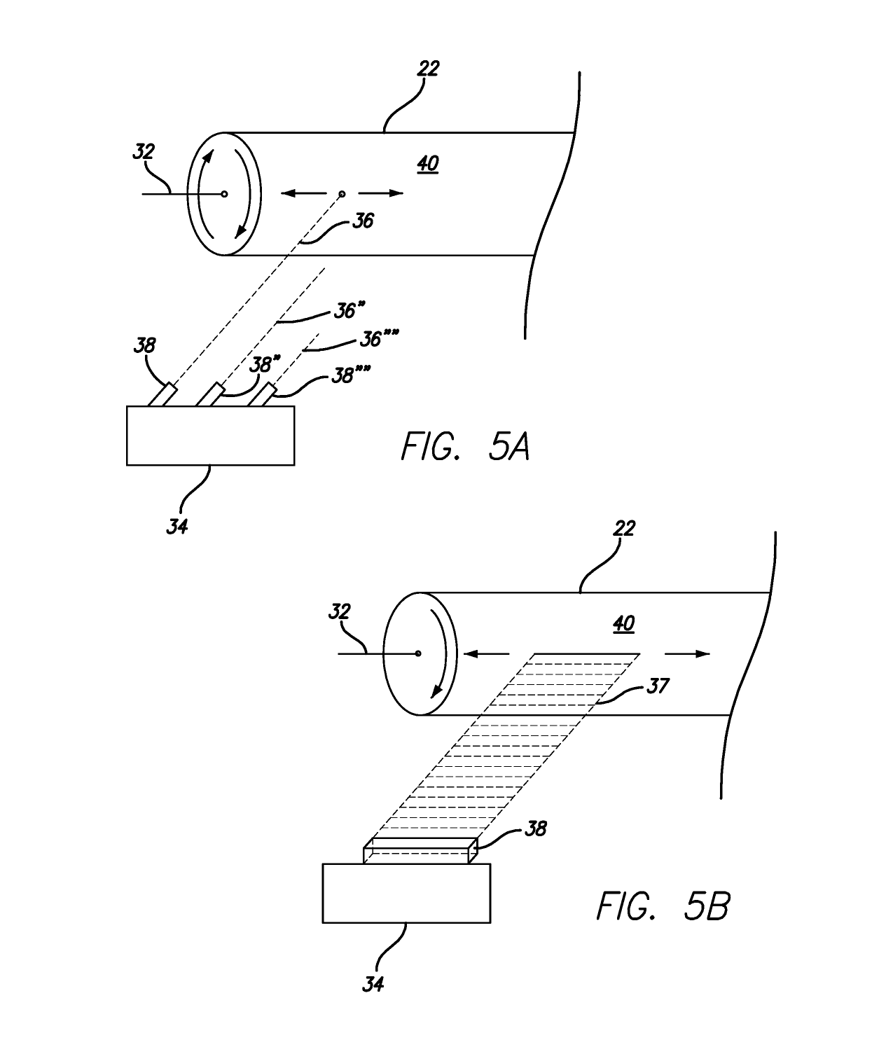

The next step as shown in FIG. 1 is to energize a microwave device 106 that produces a beam of energized protons or ions capable of penetrating into the outer surface of the ingot 22 as it rotates about the axis 32. Here, FIGS. 5A and 5B illustrate two examples a microwave device 34 for use with the processes disclosed herein. In some embodiments, the microwave device 34 may include a klystron (i.e., an electron tube used to generate or amplify electromagnetic radiation in the microwave region by velocity modulation), an electron cyclotron resonance ion source, a radio-frequency quadrupole (RFQ) accelerator, or any other high current particle accelerator. The microwave device 34 may generate a proton beam 36 (FIG. 5A) or an elongated proton beam 37 (FIG. 5B) out from an accelerator 38 directed toward the outer surface 40 of the ingot 22. In some embodiments, the accelerator 38 may include a Direct Current Gun or a Pelletron accelerator, but other comparable accelerator devices known in the art, such as a radio frequency (“RF”) accelerator, may be used as well. The accelerator 38 (e.g., an RF resonant cavity) guides microwaves from the microwave device 34 into a resonant cavity to produce high gradient electromagnetic fields that accelerate protons to a desired energy level. This minimizes the size of the microwave device 34 (high eV/m), while maintaining high production value. In this respect, one microwave device 34 may be attached to many RF resonant accelerating cavities (for example, the additional accelerators 38′, 38″ as illustrated in FIG. 5A) by use of a highway of intersecting electromagnetic waveguides. Thus, an entire factory yielding Gigawatt per year production of PV material can be powered by just a single microwave device 34. The resonant cavities are designed to maximize the quality factor, or Q value, thus minimizing the needed input energy of the microwave source.

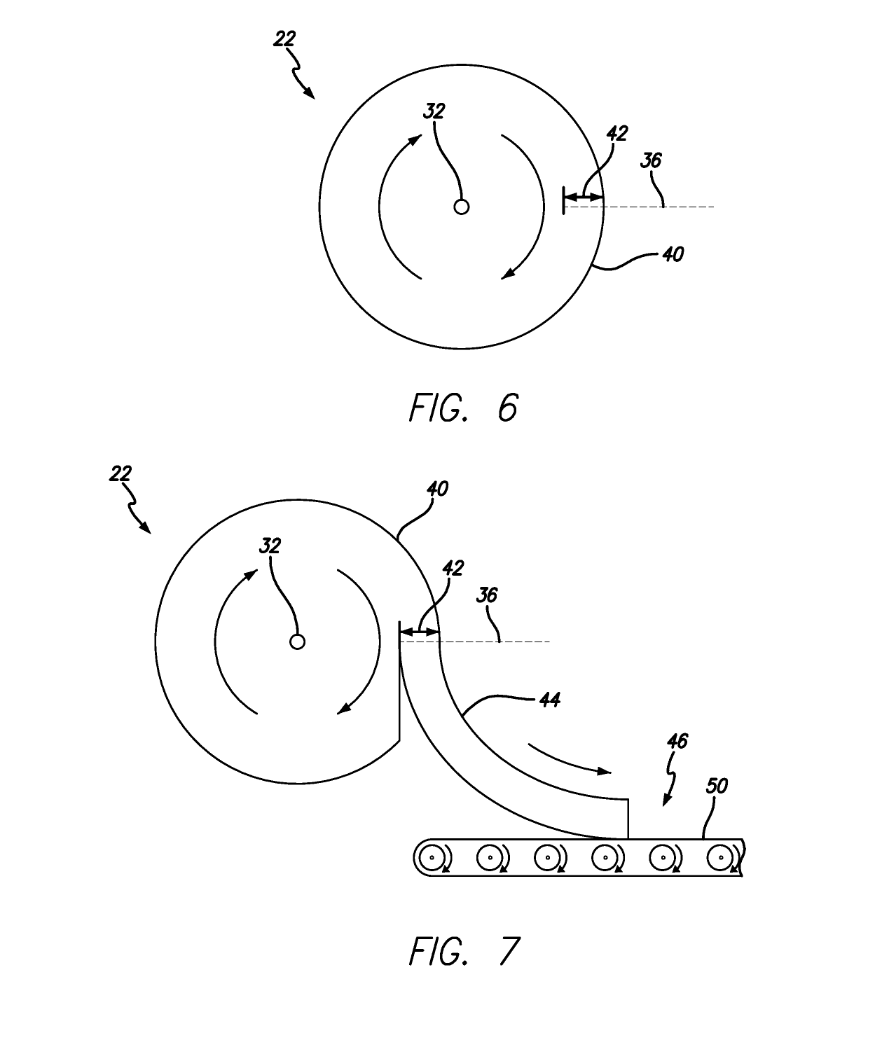

The next step as shown in FIG. 1 is to penetrate a selected layer of the ingot 22. In the embodiment wherein the ingot 22 is rotating, the penetration preferably occurs approximately parallel to an axis of rotation 108 of the ingot 22. Exemplary devices known in the art for penetrating and essentially exfoliating a select surface depth of wafer material are shown and described, for example, in the aforementioned U.S. Pat. No. 7,939,812 to Glavish et al., U.S. Pat. No. 7,982,197 to Smick et al., U.S. Pat. No. 7,989,784 to Glavish et al., and U.S. Pat. No. 8,044,374 to Ryding et al. Here, the proposed method bombards the outer surface 40 of the ingot 22 to a predetermined depth 42 (FIG. 6) with the proton beam 36, 37 having energized protons preferably ranging in energy level from 0.2-2.5 megaelectron volt (“MeV”). Accordingly, the protons penetrate the ingot 22 to a skin depth 42 of approximately 3-30 micrometers. As the ingot 22 rotates about its axis 32, the proton beam 36, 37 continuously energizes a new layer of the outer surface 40. Of course, the depth 42 may vary depending on the type of microwave device, the energy level generated within the proton accelerator 38, etc. This proton bombardment step 108 allows a layer 44 of the bombarded surface 40 to be peeled or exfoliated away from the body of the ingot 22 and onto a continuous conveyor 46 as generally shown in FIG. 7. The skin depth 42 may range from 3-30 micrometers depending on the energy of the injected protons.

During step 108, the bombarded surface of the ingot 22 increases in temperature as a result of the proton beam 36, 37. As such, a cooling mechanism is preferably utilized to cool the outer surface 40 of the ingot 22 to prevent adverse or unexpected changes in the material properties of the ingot 22 due to heating. In this respect, it is particularly important to cool the area in and around the ingot 22 being exfoliated. Water or air circulation-based cooling devices may be used with the processes disclosed herein to provide either direct or indirect cooling of the ingot 22.

The thickness of the exfoliated layer 44 is exaggerated in FIGS. 6 and 7 for illustrative purposes. In this respect, a person of ordinary skill in the art will readily recognize that relative thicknesses of this exfoliated layer 44 will be much thinner than the initial thickness of the ingot 22 made in accordance with step 100. In one embodiment, as the ingot 22 is continuously exfoliated about its axis 32, its diameter will decrease in size and the relative size differential relative to the depth 42 of the exfoliated layer 44 will decrease.

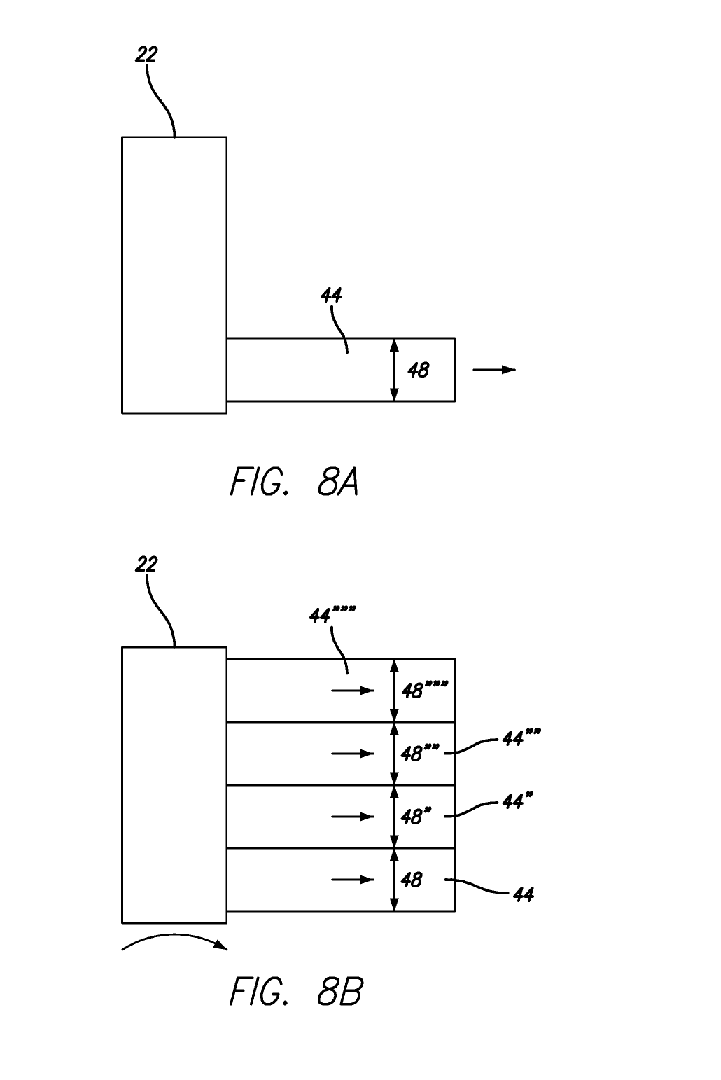

In general, the beam 36 or the elongated beam 37 needs to energize a portion of the ingot 22 along its length thereof in accordance with the desired width of the resultant wafer. This process may vary depending on the type of beam 36, 37 and the length of the ingot 22 created in step 100. For example, FIG. 5A illustrates one embodiment wherein a single beam 36 emits from one accelerator 38. Here, the beam 36 contacts a portion of the outer surface 40 at a single point. To create the layer 44 having a width 48 (FIGS. 8A, 8B), the beam 36 may move left-to-right and right-to-left along the longitudinal axis of the ingot 22 (i.e., parallel to the height or axis 32 of the ingot 22) to energize the full width 48 of the ingot 22. In this embodiment, the ingot 22 may incrementally rotate to allow the beam 36 to successfully traverse the width 48. Once it has done so, the ingot 22 rotates forward so the next increment of the outer surface 40 can be energized and exfoliated away from the body of the ingot 22. Additional accelerators 38′, 38″, 38ⁿ producing additional beams 36′, 36″, 36ⁿ may be included with the microwave device 34 so that the entire width of the ingot 22 can be processed and exfoliated simultaneously to create, for example, layers 44, 44′, 44″ as shown in FIG. 8B. Alternatively, in lieu of moving any one of the beams 36, 36′, 36ⁿ, the accelerators 38, 38′, 38ⁿ, or the microwave device 34, the ingot 22 itself may traverse back and forth.

Alternatively, as shown in FIG. 5B, the microwave device 34 may produce the elongated beam 37 having a beam width equal to the width 48 of the desired finalized wafer. Similar to that described above with respect to the beam 36, multiple elongated beams 37, 37′, 37ⁿ (additional beams 37′, 37ⁿ not shown in FIG. 5B) may be used to exfoliate part of or substantially the entire width of the ingot 22 in a manner similar to that described above with respect to FIG. 8B. The advantage of using one or more of the elongated beams 37 is that it may not be necessary to stop or increment rotation of the ingot 22 about its axis 32. In this respect, rotation and cooling of the ingot 22 may be timed to specifically facilitate continuous exfoliation as the beam 37 would not otherwise require longitudinal movement along the length of the ingot 22, as does the beam 36.

The next step as shown in FIG. 1 is to remove the layer of penetrated wafer material from the ingot 110. As described above with respect to one embodiment, the ingot 22 may rotate angularly about the axis of rotation 32 so that the beam 36, 37 does not overlap any previously bombarded area of the surface 40. As the bombardment process continues, the layer 44 of exfoliated material peels away from the ingot 22 on to the conveyor 46. The conveyor 46 may include a metal substrate 50 or other comparable surface having a high enough coefficient of friction to grasp or pull the exfoliated layer 44 away from the ingot 22, as generally shown in FIG. 7. This prevents the exfoliated layer 44 from bunching near the surface 40 as the ingot 22 rotates.

The rotation of the ingot 22 permits simultaneous exfoliation and removal of exfoliated material in a single, continuous sheet. More specifically, as the ingot 22 rotates, the portion of the outer surface 40 of the ingot 22 being exfoliated changes as the angular position of the ingot 22 changes. Simultaneously, this rotation causes the layer of exfoliated wafer 44 material to peel off of the ingot 22 as the ingot 22 rotates. Since the exfoliated layer 44 continuously peels off the ingot 22 as its angular position changes, a single continuous sheet of wafer material is produced. That is, the rotating ingot 22 “unwinds” in the same manner that a roll of paper or a coil of metal. This process provides a large savings over conventional exfoliation processes since a continuous sheet of exfoliated wafer material is produced.

The removal step 110 may produce a ribbon of one or more substrate layers 44, 44′, 44ⁿ (e.g., as shown in FIG. 8B) of wafer material 3-30 micrometers thick, depending on the bombarding proton energy. The ingot 22 moves forward a distance equal to the width of the metal substrate producing exactly enough material to be exfoliated onto the metal substrate 50 of the conveyor 46. The width of the metal substrate will correspond to the width 48 of the bombarded ingot surface, and can range from 160-200 mm.

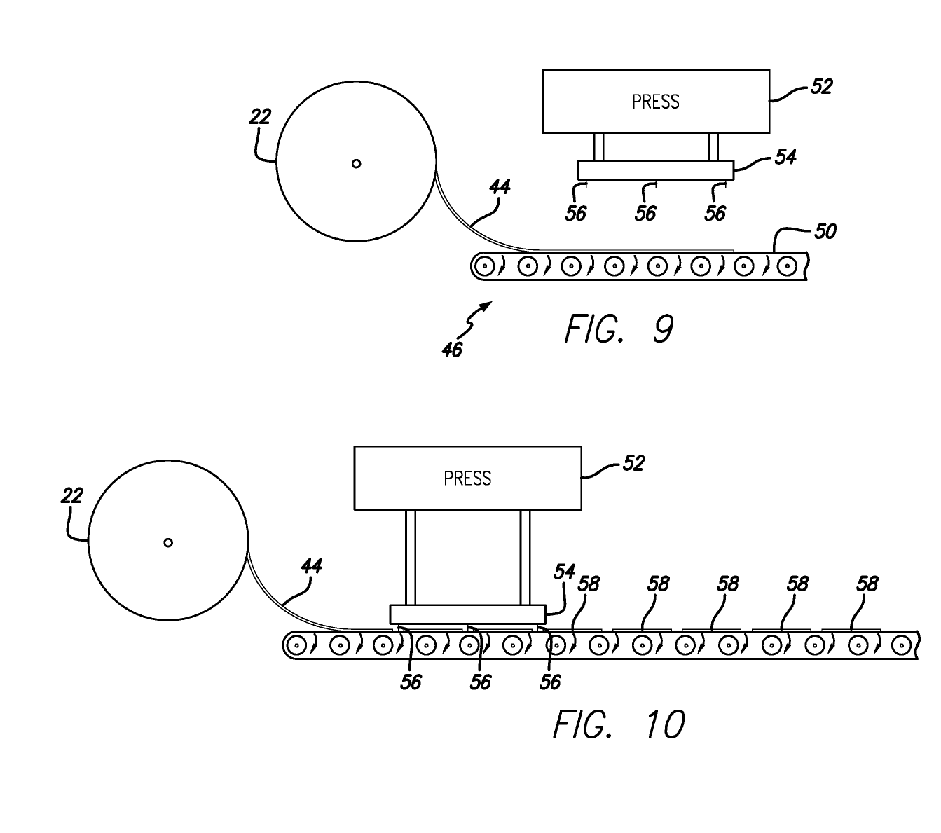

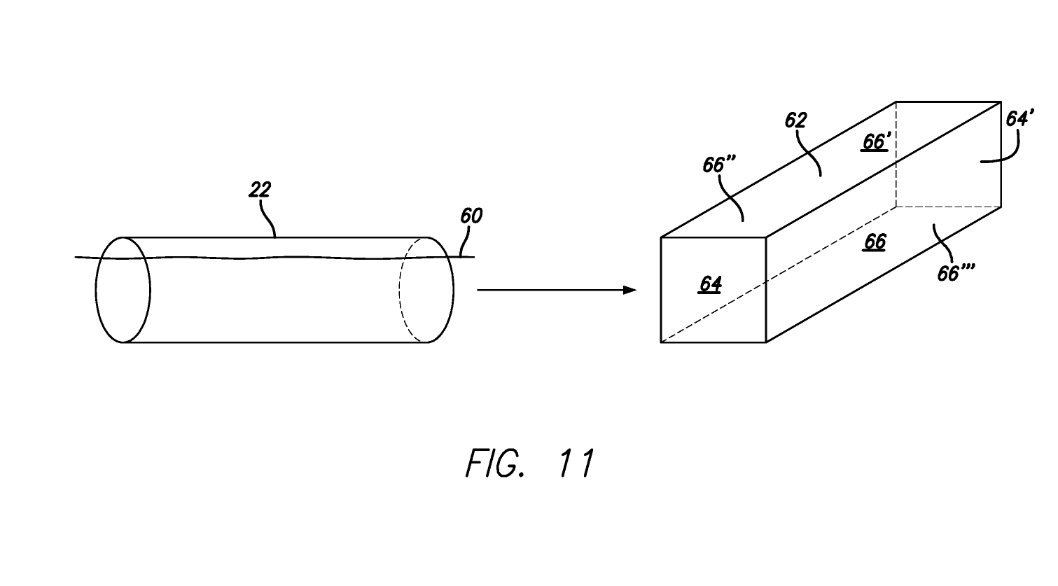

This new ribbon or layer 44 of metal substrate with PV material is then conveyed away from the ingot 22 during step 112 for subsequent stamping 114 into individual wafers (FIG. 1). In this respect, FIG. 9 illustrates movement of the layer or strip of exfoliated wafer material 44 away from the ingot 22 and toward a press 52 having a die 54 with one or more blades 56 designed to cut or shear the ribbon or layer 44 into individual wafers 58 (FIG. 10) at specific intervals. For example, when the press 52 extends the die 54 downwardly as shown in FIG. 10, the blades 56 contact and cut the strip of wafer material 44 into wafers 58 at intervals such as every 160-200 mm, thereby producing 160×160 mm wafers or 200×200 mm wafers. While these sizes may be the current dimensions of an average square PV wafer, the size of the wafer 58 should not be limited thereto. That is, the resultant size of the wafer 58 could be larger or smaller depending on the technology used to cut the layer 44 into the individual wafers 58. Furthermore, any device known in the art for slicing or cutting strips of wafer material may be utilized to create the wafers 58 from the strip or layer 44, such as alternative stamping or sawing mechanisms. Preferably, such a cutting or sawing step should create as little residual wafer material waste as possible. At this point, the final product is a square or rectangular PV wafer 58 that can run through conventional wiring and packaging machinery to produce a complete solar panel for use in residential, commercial, or utility scale solar energy production.

Of course, the processes and apparatuses described above should not be limited only to use with cylindrical ingots. Such processes and apparatuses may be applied to ingots of various shapes, sizes and materials (e.g., any type IV semiconductor, such as monocyrstalline or polycrystalline silicon or germanium, or any type III-V semiconductor material such as gallium arsenide, indium phosphide, boron nitride, boron phosphide, boron arsenide, aluminum nitride, aluminum phosphide, aluminum arsenide, aluminum antimonide, gallium nitride, gallium phosphide, gallium antimonide, indium nitride, indium arsenide, indium antimonide, etc.), including any type of metal material cast into a shape suitable for further processing as disclosed herein, including FZ silicon.

For example, the ingot 22 may have a polygonal cross section. An ingot having such a shape may be rotated about its longitudinal axis in the same manner as a cylindrical ingot. Most rotationally processed work pieces (i.e. work pieces turned on a rotator or lathe) must be cylindrical so the tool (i.e. lathe cutter) remains in contact with the work piece throughout the entire 360-degree rotation thereof. The exfoliation process, however, does not require a fixed position tool to remain in constant contact with the ingot. Instead, an energized beam that can accommodate the varying rotational diameter of a non-circular, rotating object preferably processes the work piece ingot. That is, the energized beam bombards the outer surface of the ingot and penetrates a layer of wafer material even though the diameter of the rotating ingot has a polygonal cross section that varies angularly. Therefore, ingots having a polygonal cross section may be exfoliated in the same manner as cylindrical ingots, as discussed in greater detail above.

Additionally, the wafer material may not necessarily be limited to those materials described above. In fact, any suitable material known in the art for construction of wafers may be used, including, but not limited to, float zone silicon (“FZ silicon”), polycrystalline silicon, cadmium telluride, sapphire crystal, and copper indium gallium selenide. Moreover, the wafer material can be either an n-type or p-type material. Obviously, the type and concentration of dopants and the specific processing parameters, such as temperatures, may vary depending on the choice of wafer material.

In an alternative manufacturing process similar to the processes described above with respect to steps (100)-(114), instead of using the cylindrical ingot 22 as shown in FIGS. 3-10, the ingot 22 could be initially cut or squared-off by a diamond wire 60 or other comparable cutting mechanism to form a generally rectangular semiconductor block 62 as shown generally in FIG. 11. Of course, the semiconductor block 62 could be cut as a rectangle or square, and could be cut to a number of different sizes or shapes, as desired. In the embodiment shown in FIG. 11, the semiconductor block 62 has a front work surface 64 (and similarly shaped rear work surface 64′) and a side work surface 66 (and corresponding other side work surfaces 66′-66′″) of up to three feet long, all of which are preferably ready for exfoliation in accordance with the embodiments described herein. For purposes of simplicity, the exfoliation process is described below with respect to the front work surface 64 and the side work surface 66, but the exfoliation process may work equally well alone or simultaneously with one or more of the work surfaces 64′ and 66′-66″.

Alternatively, the exfoliation process disclosed herein could be used with semiconductor wafers that have already been cut into thicknesses on the order of 200-600 microns by methods known in the art. In this respect, these existing or pre-cut semiconductor wafers could be exfoliated to form multiple thinner wafers on the order of 2-70 micrometers, or more preferably on the order of 4-20 micrometers. For example, a 300 micrometer pre-cut semiconductor wafer could be exfoliated with the processes disclosed herein to produce 12 semiconductor wafers having a 25 micrometer thickness. Such pre-cut semiconductor wafers would essentially be used as a work piece in place of the semiconductor block 62 described below in more detail. In general, the processes disclosed herein may be able to form semiconductor wafers (pre-cut or final formed) between about 2 micrometers and 1 meter.

Once the semiconductor block 62 has been created using methods known in the art, the semiconductor block 62 may be mounted for preparation of the exfoliation process, in accordance with the embodiments described above, or other embodiments known in the art. Although, one difference is that the semiconductor block 62 need not be rotated as described above with respect to the cylindrical silicon ingot 22 because the work surfaces 64, 66 provide a planar exfoliating surface as opposed to a rounded or cylindrical work surface that requires rotation about its axis to produce a flat wafer material.

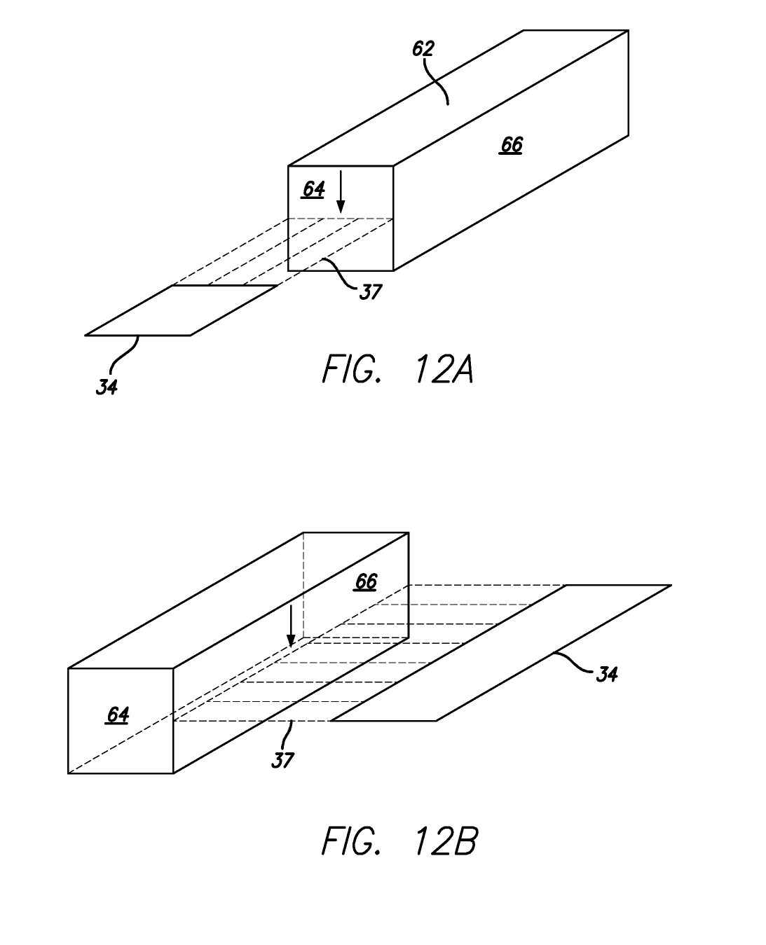

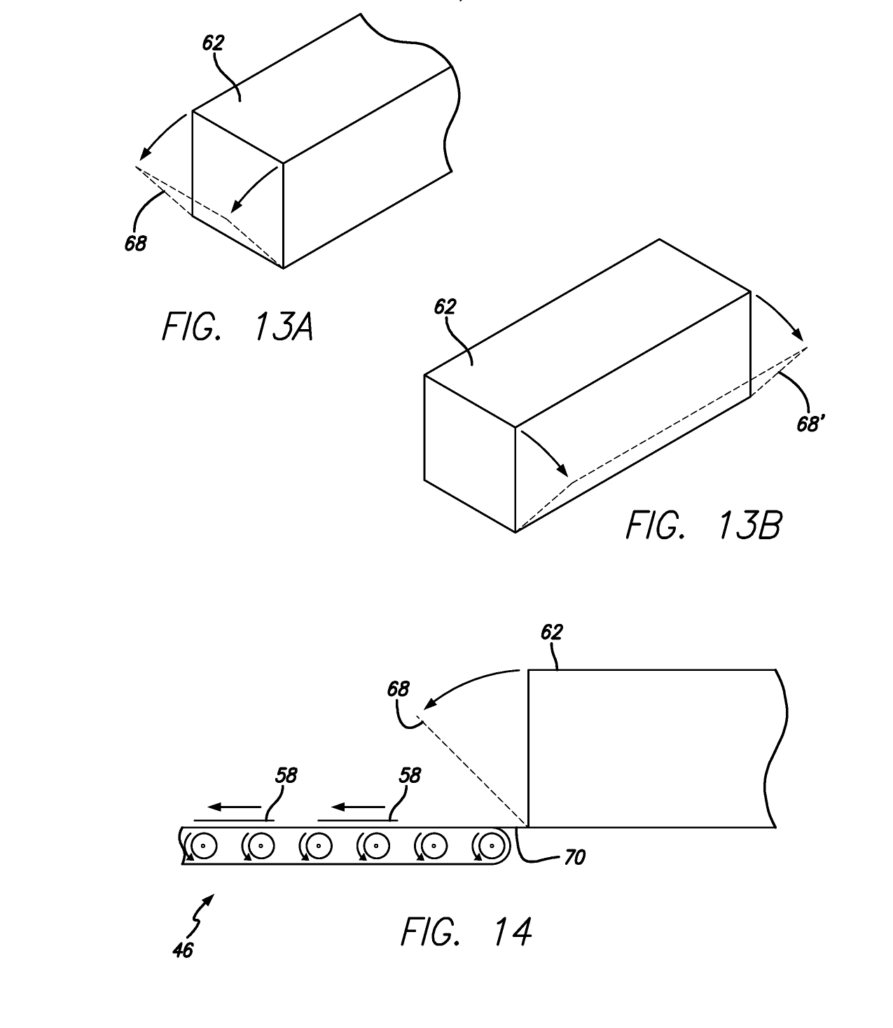

In this respect, FIGS. 12A and 12B illustrate two methods of exfoliating the outer work surfaces 64, 66 described above. For example, in FIG. 12A, the microwave device 34 produces the elongated proton beam 37 for contact about the width of the front work surface 64. The beam 37 is preferably moved top down as indicated by the directional arrow. FIG. 12B illustrates a similar embodiment, wherein the microwave device 34 produces similar elongated proton beam 37 that preferably spans the width of the side work surface 66 and moves top-down as indicated by the directional arrow. In this respect, as shown in FIGS. 13A and 13B, an exfoliated layer of semiconductor material 68, 68′ begins to exfoliate off or peel away from the semiconductor block 62, in accordance with the embodiments described above. Similarly, this exfoliated layer 68 or 68′ may be conveyed away from the work piece 62 by a conveyor 46 or the like (FIG. 14). The exfoliation process could create individual semiconductor wafers 58, for example by exfoliating a front work surface 64 that matches the desired dimensions of the resultant semiconductor wafer 58, or by exfoliating a larger area (e.g., by way of the side work surface 66), and then later cutting the strip of exfoliated semiconductor material into strips as described above with respect to the exfoliated layer 44.

One particular advantage of the embodiments disclosed herein is the use of the exfoliation process with semiconductor materials having relatively lower oxygen content (e.g., 10¹⁵ oxygen atoms per cubic centimeter). On one hand, current solar grade silicon material used to create silicon wafers sized for use in solar panels have a relatively higher oxygen content (e.g., 10¹⁸ oxygen atoms per cubic centimeter) and are produced by the Czochralski process. These silicon wafers only have an efficiency of 19%-20%, but are economical to produce. On the other hand, silicon materials having a comparatively low oxygen content and therefore higher efficiency (e.g., float zone silicon wafers have an efficiency of approximately 24.7%) must be cut into larger than desired sizes (e.g., on the order of 300-500 microns in thickness) because the rigid material properties prevent known methods (e.g., a diamond wire) from cutting the material any thinner. Thus, silicon wafers made from float zone silicon or the like are currently cost prohibitive due to material costs and the currently available minimum manufacturing thickness of the wafers.

Accordingly, the exfoliation processes described above are particularly useful in economically producing semiconductor wafers from a higher grade semiconductor material (e.g., float zone silicon) that has a relatively lower oxygen content and a smaller thickness (e.g., 2-70 microns, and preferably 4-20 microns, as opposed to 100+ microns). This is accomplished by bombarding the surface area structure of the semiconductor material with the aforementioned methods for ion implantation, such as by way of the microwave device 34 (e.g., a DC accelerator or other beam having enhanced energy levels). The surface area bombardment is particularly preferred over known methods because the surface area tension of higher purity semiconductor material prohibits physically sawing off (e.g., by a diamond wire) wafers to economical thicknesses (e.g., under 100 microns).

As shown in FIGS. 13A, 13b and 14, the exfoliated layer 68 or 68′ peels away from the semiconductor block 62 by a thickness determined by the energy level of the ions bombarding the surface thereof. In this respect, increasing the energy level of the beam 37 results in deeper surface level penetration and a thicker wafer 58, while decreasing the energy level of the beam 37 results in shallower surface level penetration and a thinner wafer 58. More specifically, using the implantation density of approximately 5×10¹⁴ to 5×10¹⁶ ions/cm² will penetrate the surface level of float zone silicon to a depth sufficient to produce wafers 58 having a relative thickness of 2-70 microns, and preferably 4-20 microns. In alternative embodiments, an implantation density of approximately 1×10¹⁷ ions/cm² may produce a semiconductor wafer having a thickness of 2-70 microns, or more preferably 4-20 microns. These relatively thin wafers 58 may be placed on the conveyor 46 having a surface that includes a conductive surface or backing 70 to pull the wafers 58 away from the semiconductor block 62 as each wafer 58 is produced.

Although several embodiments have been described in detail for purposes of illustration, various modifications may be made without departing from the scope and spirit of the invention. Accordingly, the invention is not to be limited, except as by the appended claims.

What is claimed is:

1. A method for manufacturing a semiconductor wafer, comprising the steps of:
mounting a semiconductor work piece for exfoliation;
energizing a microwave device for generating an energized beam sufficient for penetrating an outer surface layer of the semiconductor work piece;
exfoliating the outer surface layer of the semiconductor work piece with the energized beam;
applying a coolant directly to the outer surface layer of the semiconductor work piece for cooling the semiconductor work piece at a penetration point where the energized beam bombards the outer surface layer of the semiconductor work piece; and
removing the exfoliated outer surface layer from the semiconductor work piece as the semiconductor wafer.

2. The method of claim 1, wherein the semiconductor work piece comprises a pre-cut semiconductor work piece having a thickness of 100 microns to 1 meter.

3. The method of claim 1, wherein the semiconductor work piece comprises a type III-V semiconductor material or a type IV semiconductor material.

4. The method of claim 3, wherein the type III-V semiconductor material comprises gallium arsenide.

5. The method of claim 3, wherein the type IV semiconductor material comprises silicon or germanium.

6. The method of claim 1, wherein the semiconductor wafer comprises a thickness less than 100 microns.

7. The method of claim 6, wherein the semiconductor wafer comprises a thickness of 2-70 microns.

8. The method of claim 1, wherein the semiconductor work piece includes an oxygen content comprising less than 10¹⁵ oxygen atoms per cubic centimeter.

9. The method of claim 1, wherein the energized beam comprises an implantation density of approximately 1×10¹⁷ ions/cm².

10. The method of claim 1, wherein the semiconductor wafer comprises a square semiconductor wafer.

11. The method of claim 1, wherein the microwave device comprises a high current particle accelerator.

12. The method of claim 11, wherein the high current particle accelerator comprises an electron cyclotron resonance ion source or a radio-frequency quadrupole (RFQ) accelerator.

13. The method of claim 1, wherein the energized beam comprises a width approximately the same as the width of the semiconductor work piece.

14. The method of claim 1, wherein the semiconductor work piece comprises a rectangular shape.

15. A method for manufacturing a semiconductor wafer, comprising the steps of:
mounting a semiconductor work piece comprising an oxygen content less than 10¹⁵ oxygen atoms per cubic centimeter;
energizing a microwave device for generating an energized beam comprising an implantation density of approximately 1×10¹⁷ ions/cm² for penetrating an outer surface layer of the semiconductor work piece;
exfoliating the outer surface layer of the semiconductor work piece with the energized beam;
applying a coolant directly to the outer surface layer of the semiconductor work piece for cooling the semiconductor work piece at a penetration point where the energized beam bombards the outer surface layer of the semiconductor work piece; and
removing the exfoliated outer surface layer from the semiconductor work piece as the semiconductor wafer comprising a thickness less than 100 micrometers.

16. The method of claim 15, wherein the semiconductor work piece comprises a pre-cut semiconductor work piece having a thickness of 100 microns to 1 meter.

17. The method of claim 15, wherein the semiconductor work piece comprises a type III-V semiconductor material selected from the group consisting of gallium arsenide, indium phosphide, boron nitride, boron phosphide, boron arsenide, aluminum nitride, aluminum phosphide, aluminum arsenide, aluminum antimonide, gallium nitride, gallium phosphide, gallium antimonide, indium nitride, indium arsenide, or indium antimonide.

18. The method of claim 15, wherein the semiconductor work piece comprises a type IV semiconductor selected from the group consisting of monocyrstalline silicon, polycrystalline silicon, or germanium.

19. The method of claim 15, wherein the semiconductor wafer comprises a thickness of 4-20 microns.

20. The method of claim 15, including the step of exfoliating the semiconductor wafer into multiple semiconductor wafers and moving each of the multiple semiconductor wafers along a conveyor.

21. The method of claim 15, wherein the semiconductor wafer comprises a square semiconductor wafer having a thickness of 2-70 microns.

22. The method of claim 15, wherein the microwave device comprises an electronic cyclotron resonance ion source or a radio-frequency (RFQ) accelerator for generating the energized beam comprising an ion beam or a proton beam, wherein the energized beam moves relative to the semiconductor work piece.

23. The method of claim 15, wherein the energized beam comprises a width approximately the same as the width of a rectangular semiconductor work piece.

24. A method for manufacturing a plurality of semiconductor wafers, comprising the steps of:
mounting a pre-cut semiconductor work piece comprising an oxygen content less than 10¹⁵ oxygen atoms per cubic centimeter and having a thickness of 160-600 microns, the semiconductor work piece comprising a type III-V semiconductor selected from the group consisting of gallium arsenide, indium phosphide, boron nitride, boron phosphide, boron arsenide, aluminum nitride, aluminum phosphide, aluminum arsenide, aluminum antimonide, gallium nitride, gallium phosphide, gallium antimonide, indium nitride, indium arsenide, or indium antimonide;
energizing a microwave device comprising an electron cyclotron resonance ion source or a radio-frequency quadrupole (RFQ) for generating an energized beam sufficient for penetrating an outer surface layer of the semiconductor work piece;
exfoliating the outer surface layer of the semiconductor work piece with the energized beam;
applying a coolant directly to the outer surface layer of the semiconductor work piece for cooling the semiconductor work piece at a penetration point where the energized beam bombards the outer surface layer of the semiconductor work piece;
removing the exfoliated outer surface layer from the semiconductor work piece as the semiconductor wafer comprising a thickness of 2-70 microns; and
cutting the semiconductor wafer into multiple semiconductor wafers.

25. An apparatus for manufacturing a plurality of semiconductor wafers from a semiconductor work piece, comprising:
a mount for selectively receiving and retaining the semiconductor work piece having an exfoliation surface;
a microwave positioned relative to the mount to emit an energized beam in the direction of the exfoliation surface, wherein relative movement of the microwave and the semiconductor work piece exfoliates a semiconductor wafer therefrom;
a fluid cooler positioned to apply a coolant directly to an outer surface layer of the semiconductor work piece to cool a penetration point where the energized beam bombards the outer surface layer of the semiconductor work piece for controlling a surface temperature of the semiconductor work piece; and
a handle removing each of the plurality of semiconductor wafers exfoliated from the exfoliation surface away from the semiconductor work piece.

26. The apparatus of claim 25, wherein the semiconductor work piece comprises a type IV semiconductor selected from the group consisting of monocyrstalline silicon, polycrystalline silicon, or germanium, or a type III-V semiconductor selected from the group consisting of gallium arsenide, indium phosphide, boron nitride, boron phosphide, boron arsenide, aluminum nitride, aluminum phosphide, aluminum arsenide, aluminum antimonide, gallium nitride, gallium phosphide, gallium antimonide, indium nitride, indium arsenide, or indium antimonide.

27. The apparatus of claim 25, wherein the microwave device comprises an electron cyclotron resonance ion source or a radio-frequency quadrupole (RFQ) and the energized beam comprises an elongated beam approximately the width of the exfoliation surface.

28. The apparatus of claim 25, wherein the semiconductor work piece comprises a rectangular shape and the fluid cooler comprises an air cooler.

29. The apparatus of claim 25, wherein the semiconductor work piece comprises an oxygen content less than 10¹⁵ oxygen atoms per cubic centimeter.

30. The apparatus of claim 25, wherein the semiconductor wafer comprises a thickness less than 100 microns.
